(19) United States
(12) Patent Application Publication
(10) Pub. No.: US 2018/0053869 A1
(43) Pub. Date: Feb. 22, 2018

(54) SOLAR CELL PANEL AND WINDOW HAVING THE SAME

(71) Applicant: KOREA INSTITUTE OF SCIENCE AND TECHNOLOGY, Seoul (KR)

(72) Inventors: Hyungduk KO, Seoul (KR); Gi Yong LEE, Seoul (KR); S. Joon KWON, Seoul (KR); Il Ki HAN, Seoul (KR); Kinam JUNG, Seoul (KR)

(21) Appl. No.: 15/260,742

(22) Filed: Sep. 9, 2016

(30) Foreign Application Priority Data
Aug. 18, 2016 (KR) 10-2016-0104594

(51) Int. Cl. H01L 31/054; H01L 31/0468; H02S 20/26

(52) U.S. Cl. CPC H01L 31/0547; H02S 20/26; H01L 31/0468

(57) ABSTRACT

Provided are a solar cell panel and a window having the same. The solar cell panel includes: a light diffusion layer to which light is incident and at which the light is scattered; a light concentration layer laminated at a lower portion of the light diffusion layer and having a plurality of patterns spaced apart from each other and having a cavity shape convex toward the light diffusion layer at a surface thereof opposite to the light diffusion layer so that light passing through the light diffusion layer is reflected and concentrated to a side portion thereof; and a solar cell array provided at a side surface of the light concentration layer and having a plurality of solar cells arranged along the side surface of the light concentration layer and electrically connected to each other.

### CROSS-REFERENCE TO RELATED APPLICATIONS

This application claims, under 35 U.S.C. § 119, the priority of Korean Patent Application No. 10-2016-0104594 filed on Aug. 18, 2016 in the Korean Intellectual Property Office, the disclosure of which is incorporated herein by reference in its entirety.

### TECHNICAL FIELD

The following disclosure relates to a solar cell panel and a window having the same, and in particular, to a large area solar cell panel having highly efficient transmission and no increase in thickness and a window having the same.

### BACKGROUND

Recently, solar energy generation facilities capable of producing power from solar energy are being gradually propagated.

A solar cell using solar energy does not use fossil fuels such as petroleum and coal and uses pollution-free solar energy which is an infinite energy source. Thus, the solar cell is spotlighted as a new alternative energy source and is being used for producing power in solar energy power plants and vehicles in these days.

Solar energy power generation is applied in various fields, among which a building integrated photovoltaic (BIPV) technique using solar cells as an exterior finishing material of a building is spotlighted as a prominent new technology for the 21^{st} century.

Even though an exterior of an existing structure is just used for protecting the building against external environments, in the BIPV technique, the exterior of a building is actively used as a tool for creating energy. Thus, the exterior of a building using the BIPV technique may have a key part in supplying solar cells and reduce costs required for installing an existing solar energy generation system.

A solar window configured by coupling solar cells to a window is an example of the above configuration in which solar cells are used as an exterior of a building. The obligation to build a zero-energy structure is in progress not only in this country but also over the world by 2020, and thus the need for a self-energy production technique of a building such as the solar window is arising.

In order to apply the solar window to a building, a large-sized high-efficient solar cell technology ensuring long-term stability and good aesthetic property is demanded.

However, in an existing solar window, a solar cell module is simply interposed between a pair of glass panels, or a solar cell module is attached to one side of a glass board, which has bad efficiency and bad appearance and is not suitable for a large-sized window.

Recently, a solar concentrating method has been actively studied to improve the efficiency of the solar window, and International Patent Publication WO 2015/079094 (Jun. 4, 2015) and Solar Energy Materials & Solar Cells 84 (2004) 411-426 disclose a solar concentration device applicable to the solar window.

FIG. 1 is a diagram showing the solar concentration device disclosed in International Patent Publication WO 2015/079094, and FIG. 2 is a diagram showing the solar concentration device disclosed in Solar Energy Materials & Solar Cells 84 (2004) 411-426.

Referring to FIG. 1, the solar concentration device disclosed in International Patent Publication WO 2015/079094 includes a photonic crystal coating 2 disposed at an upper surface of a transparent or semi-transparent substrate 4, a layer of luminescent material 3 disposed at an upper surface of the photonic crystal coating 2, and photovoltaic cells 1A, 1B disposed in parallel at the substrate 4. In addition, a sealant 5 is provided to seal a region between the substrate 4 and a top sheet 6 prepared at an upper portion of the substrate 4.

In the solar concentration device disclosed in International Patent Publication WO 2015/079094 as above, a wavelength of incident light is converted by the layer of luminescent material 3, and then the incident light is guided to the photovoltaic cells 1A, 1B by means of the photonic crystal coating 2.

Also, referring to FIG. 2, the solar concentration device disclosed in Solar Energy Materials & Solar Cells 84 (2004) 411-426 is configured so that luminescent solar concentrators (LSCs) having three colors are laminated. In detail, luminescent solar concentrators (LSCs) doped with violet, green and pink pigments are laminated.

In the solar concentration device disclosed in Solar Energy Materials & Solar Cells 84 (2004) 411-426, a wavelength of incident light is converted using three kinds of luminescent solar concentrators (LSCs) which allow wavelength conversion from short wavelength to long wavelength, and the incident light is transmitted to a side, where photovoltaic cells are located, through an end mirror, a reflector and a light guide.

In the above existing techniques, incident light is converted into a specific wavelength and then guided or transmitted toward a solar cell, which has low solar energy generation efficiency and low light transmission and also increases thickness of a window.

### RELATED LITERATURES

### Patent Literature

International Patent Publication WO 2015/079094

### Non-patent Literature

Optimisation of a three-colour luminescent solar concentrator daylighting system, Solar Energy Materials & Solar Cells 84 (2004) 411-426

### SUMMARY

An embodiment of the present disclosure is directed to providing a large area solar cell panel having highly efficient transmission and no increase in thickness, and a window having the same.

In one general aspect of the present disclosure, there is provided a solar cell panel, comprising: a light diffusion layer to which light is incident and at which the light is scattered; a light concentration layer laminated at a lower portion of the light diffusion layer and having a plurality of patterns spaced apart from each other and having a cavity shape convex toward the light diffusion layer at a surface thereof opposite to the light diffusion layer so that light passing through the light diffusion layer is reflected and concentrated to a side portion thereof; and a solar cell array provided at a side surface of the light concentration layer and having a plurality of solar cells arranged along the side surface of the light concentration layer and electrically connected to each other.

The plurality of patterns may configure a matrix form.

The plurality of patterns may have a cycle of 1 to 2000 μm.

The pattern may have a width of 1 to 1000 μm and a height of 1 to 1000 μm.

The light concentration layer may be formed with a glass substrate, and the patterns having a cavity shape convex toward the light diffusion layer may be formed at a surface thereof opposite to the light diffusion layer by means of etching or laser processing.

The light diffusion layer and the light concentration layer may configure a single unit light concentration module, one or more unit light concentration modules may be laminated in a height direction, and the solar cell arrays may be provided respectively at sides of the unit light concentration modules according to the number of the unit light concentration modules and electrically connected to each other.

In another aspect of the present disclosure, there is provided a window having a solar cell panel, comprising: a solar cell panel; and a window frame coupled along an edge of the solar cell panel, wherein the solar cell panel includes: a light concentration module having a light diffusion layer to which light is incident and at which the light is scattered, and a light concentration layer laminated at a lower portion of the light diffusion layer and having a plurality of patterns spaced apart from each other and having a cavity shape convex toward the light diffusion layer at a surface thereof opposite to the light diffusion layer so that light passing through the light diffusion layer is reflected and concentrated to a side portion thereof; and a solar cell array coupled to a side surface of the light concentration module.

The plurality of patterns may configure a matrix form.

The plurality of patterns may have a cycle of 1 to 2000 μm.

The pattern may have a width of 1 to 1000 μm and a height of 1 to 1000 μm.

When a plurality of the light concentration modules is laminated in a height direction, the solar cell arrays may be provided respectively at sides of the unit light concentration modules according to the number of the unit light concentration modules and electrically connected to each other.

An embodiment of the present disclosure may provide a high-efficient high-transmission solar cell panel and a window having the same, in which incident light is not converted into a specific wavelength but all wavelengths are transmitted for power generation.

In addition, an embodiment of the present disclosure may provide a large area solar cell panel no increase in thickness and a window having the same, in which a layer of luminescent material or the like required for converting incident light into a specific wavelength is not included.

In addition, an embodiment of the present disclosure may simplify a manufacturing process for the solar cell panel and the window having the same.

### BRIEF DESCRIPTION OF THE DRAWINGS

FIG. 1 is a diagram showing a solar concentration device disclosed in International Patent Publication WO 2015/079094.

FIG. 2 is a diagram showing a solar concentration device disclosed in Solar Energy Materials & Solar Cells 84 (2004) 411-426.

FIG. 3 is a perspective view showing a window having a solar cell panel according to an embodiment of the present disclosure.

FIG. 4 is a cross-sectional view schematically showing a solar cell panel according to an embodiment of the present disclosure.

FIG. 5 is a diagram showing a light diffusion layer according to an embodiment of the present disclosure.

FIG. 6A is a plane view showing a pattern formed at the light concentration layer according to an embodiment of the present disclosure.

FIG. 6B is a cross-sectional view showing a pattern formed at the light concentration layer according to an embodiment of the present disclosure.

FIG. 7 is a plane view showing a solar cell array according to an embodiment of the present disclosure.

FIG. 8 is a side view showing the solar cell array according to an embodiment of the present disclosure.

FIG. 9 is a diagram showing a plurality of laminated light concentration modules according to an embodiment of the present disclosure.

FIG. 10A is a graph showing the degree of transmittance according to the number of laminated light concentration modules according to an embodiment of the present disclosure.

FIG. 10B is a table showing power generation efficiency of the solar cell panel according to an embodiment of the present disclosure.

FIGS. 11A and 11B are diagrams for illustrating a method for connecting plurality of solar cell arrays in series or in parallel according to an embodiment of the present disclosure.

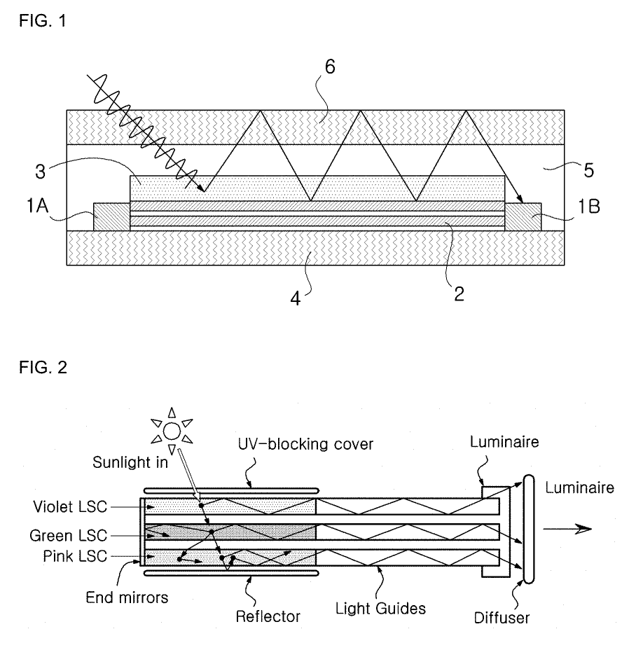

### DETAILED DESCRIPTION OF EMBODIMENTS

The present disclosure, advantages of operations of the present disclosure and objects accomplished by the implementation of the present disclosure can be sufficiently understood with reference to the accompanying drawings depicting embodiments of the present disclosure and explanations thereof.

Hereinafter, an embodiment of the present disclosure will be described in detail with reference to the accompanying drawings. In the drawings, like reference numerals denote like elements.

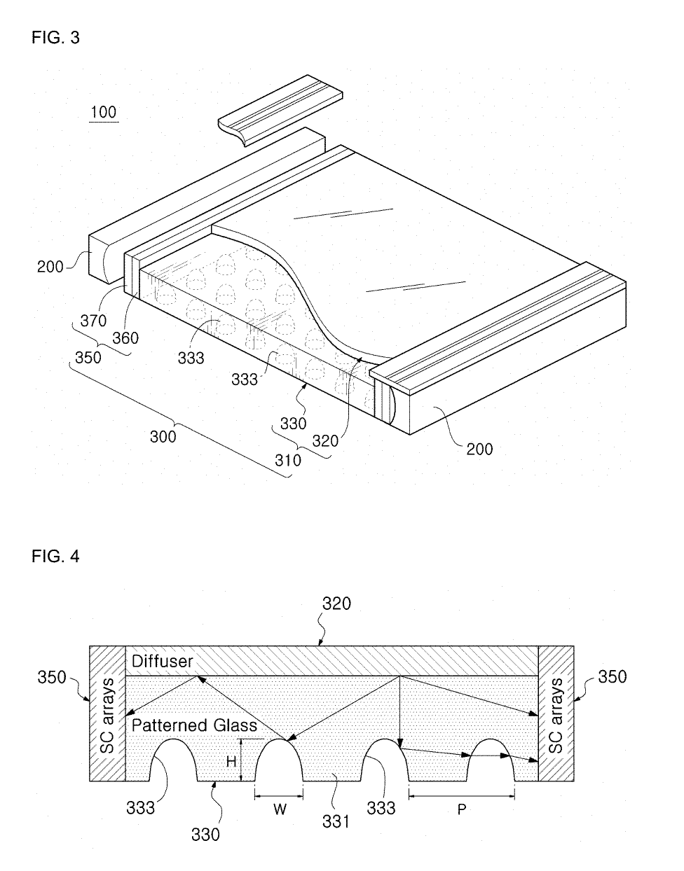

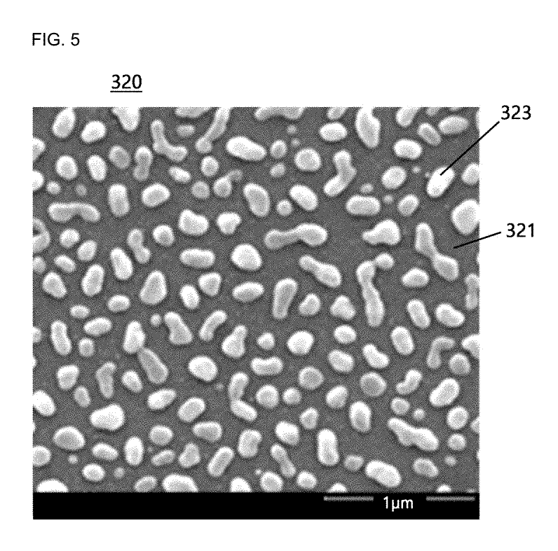

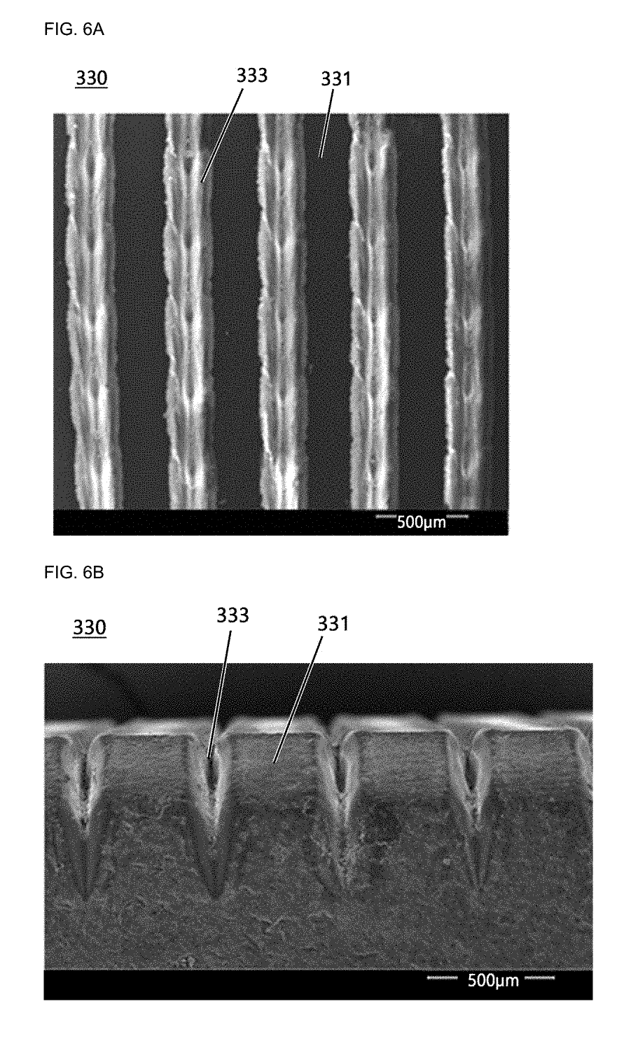

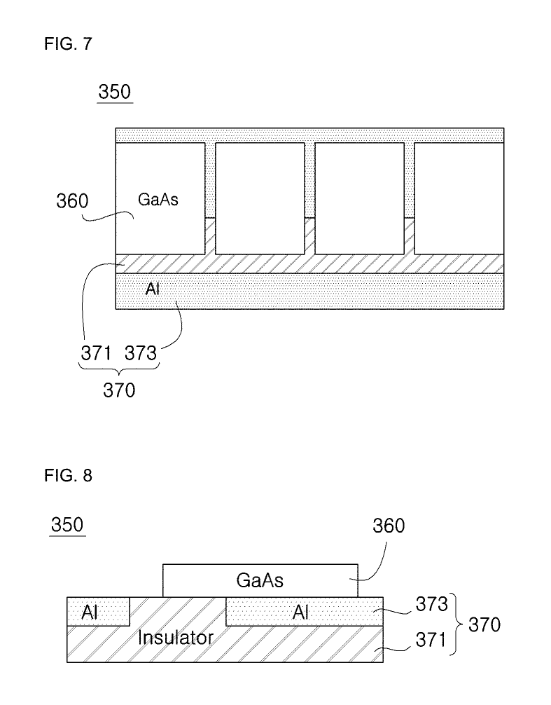

FIG. 3 a perspective view showing a window having a solar cell panel according to an embodiment of the present disclosure, FIG. 4 is a cross-sectional view schematically showing a solar cell panel according to an embodiment of the present disclosure, FIG. 5 is a diagram showing a light diffusion layer according to an embodiment of the present disclosure, FIG. 6A is a plane view showing a pattern formed at the light concentration layer according to an embodiment of the present disclosure, FIG. 6B is a cross-sectional view showing a pattern formed at the light concentration layer according to an embodiment of the present disclosure, FIG. 7 is a plane view showing a solar cell array according to an embodiment of the present disclosure, and FIG. 8 is a side view showing the solar cell array according to an embodiment of the present disclosure.

Referring to FIG. 3, a window 100 having a solar cell panel according to an embodiment of the present disclosure includes a solar cell panel 300, and a window frame 200 coupled along an edge of the solar cell panel 300.

The solar cell panel 300 according to this embodiment is coupled to the window frame 200 and plays a role of photoelectric transformation using incident light.

In addition, the solar cell panel 300 includes a light concentration module 310 for scattering and reflecting incident light to be concentrated at a side portion, and a solar cell (SC) array 350 coupled to a side surface of the light concentration module 310.

Referring to FIGS. 3 to 6, the light concentration module 310 according to this embodiment includes a light diffusion layer 320, and a light concentration layer 330 laminated at a lower portion of the light diffusion layer 320.

Referring to FIG. 4, the light diffusion layer (or, a diffuser) 320 plays a role of scattering and diffusing incident light. In addition, the light diffusion layer 320 is prepared at an upper portion of the light concentration layer 330.

As shown in FIG. 5, the light diffusion layer 320 may be configured with a glass substrate 321 having metal nano particles 323 disposed at a surface thereof to be spaced apart from each other. In other words, in the light diffusion layer 320, the metal nano particles 323 are arranged at random on the surface of the glass substrate 321 to scatter light in all directions.

In addition, the light concentration layer 330 plays a role of reflecting the light passing through the light diffusion layer 320 to be concentrated at the side portion thereof.

The light concentration layer 330 may be made using a glass substrate 331. In addition, at a surface of the light concentration layer 330 opposite to the light diffusion layer 320, namely at a lower surface of the light concentration layer 330, a plurality of patterns 333 having a cavity shape convex toward the light diffusion layer 320 are formed to be spaced apart from each other. In other words, the light concentration layer 330 may be made using a glass substrate having a plurality of patterns 333 (namely, a patterned glass).

In addition, as shown in FIGS. 3 and 4, the plurality of patterns 333 may be configured in a matrix form at the lower surface of the light diffusion layer 320. The plurality of patterns 333 are spaced apart from each other, and the plurality of patterns 333 may have a cycle (P) of 1 to 2000 μm.

In addition, each of the plurality of patterns 333 may be formed with a cavity shape having a width (W) of 1 to 1000 μm and a height (H) of 1 to 1000 μm.

FIGS. 6a and 6b show cavity-type patterns 333 formed in one direction at the lower surface of the light concentration layer 330 by means of etching or laser processing. By means of the etching or laser processing, the plurality of cavity-type patterns 333 arranged in a matrix form may be formed at the lower surface of the light concentration layer 330.

As described above, the light diffusion layer 320 and the light concentration layer 330 configure a single unit light concentration module 310 to scatter and reflect incident light and concentrate the light at a side portion thereof.

The light concentration module 310 according to an embodiment of the present disclosure concentrate incident light as follows.

As shown in FIG. 4, the light input to the light diffusion layer 320 is scattered and diffused to all directions while passing through the light diffusion layer 320.

In addition, the light diffused by the light diffusion layer 320 may be totally reflected by the plurality of cavity-type patterns 333 arranged in a matrix form at the lower surface of the light concentration layer 330 while passing through the light concentration layer 330, so that the light may be guided and concentrated to the side portion of the light concentration layer 330.

Also, the light passing through the light concentration layer 330 may be transmit through the plurality of cavity-type patterns 333 and guided and concentrated to the side portion of the light concentration layer 330.

In addition, the light passing through the light concentration layer 330 may be totally reflected by the plurality of cavity-type patterns 333 and reflected at the lower surface of the light diffusion layer 320, so as to be guided and concentrated to the side portion of the light concentration layer 330.

As described above, the light concentration module 310 according to this embodiment does not convert incident light into a specific wavelength but allows all wavelengths to pass, and guides and concentrates the light to a side portion of the light concentration layer 330, thereby obtaining high-efficient power generation effect through the solar cell array 350 provided at a side surface of the light concentration module 310.

In addition, the light diffusion layer 320 and the light concentration layer 330 of the light concentration module 310 according to this embodiment are made of glass substrates, which may improve light transmission of incident light and thus further enhance power generation efficiency.

Moreover, since the light diffusion layer 320 and the light concentration layer 330 do not include a layer of luminescent material or the like, which is required for converting incident light into a specific wavelength, the light concentration module 310 according to this embodiment may be manufactured with a large area without increasing its thickness, and its manufacturing process may be simplified.

Meanwhile, the solar cell array 350 according to this embodiment plays a role of photoelectric transformation using incident the light concentrated by the light concentration module 310.

Referring to FIGS. 7 and 8, the solar cell array 350 according to this embodiment is provided along an edge of the light concentration module 310. In detail, if the light concentration module 310 has a rectangular planar shape, the solar cell arrays 350 may be provided along four sides of the light concentration module 310.

In addition, the solar cell array 350 includes a plurality of solar cells 360 disposed along a side surface of the light concentration module 310 and electrically connected to each other, and a cell frame 370 supporting the lower surface of the solar cells 360.

The solar cells 360 may be electrically connected in series or in parallel by means of wire bonding at the upper surface of the cell frame 370. In this embodiment, the solar cells 360 may be Si-based solar cells 360 or GaAs-based solar cell 360, but the present disclosure is not limited thereto.

The cell frame 370 includes an insulation layer (or, an insulator) 371 closely adhered to a partial region of the lower surface of the solar cell 360, and a conductive layer 373 made of Al or the like and closely adhered to the lower surface of the solar cell 360 except for the region to which the insulation layer 371 is closely adhered.

Meanwhile, in the window 100 having a solar cell panel according to this embodiment, a plurality of light concentration modules 310 may be laminated in a height direction and coupled to the window frame 200.

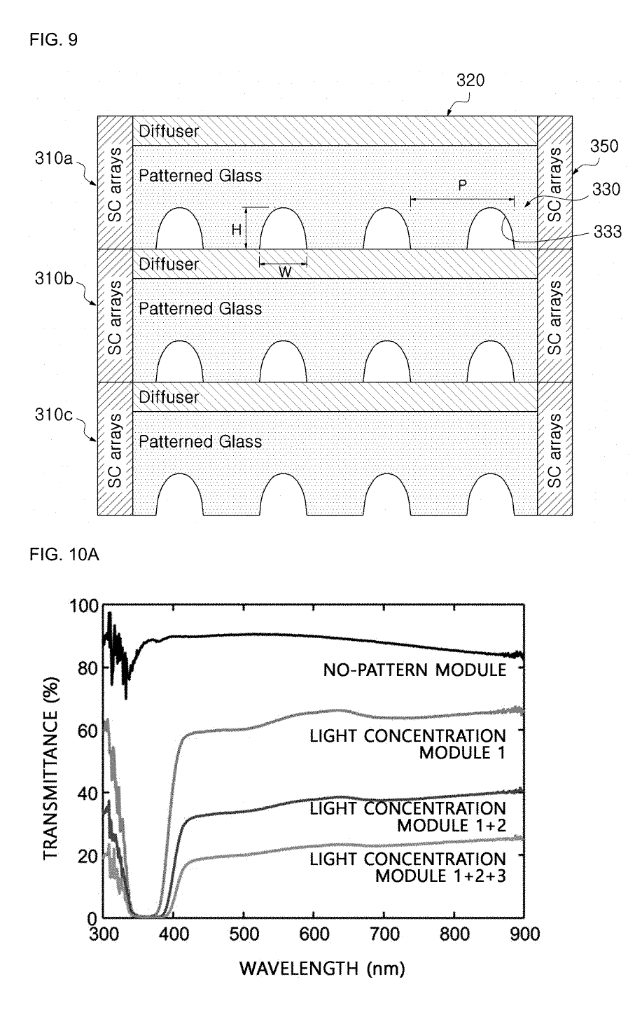

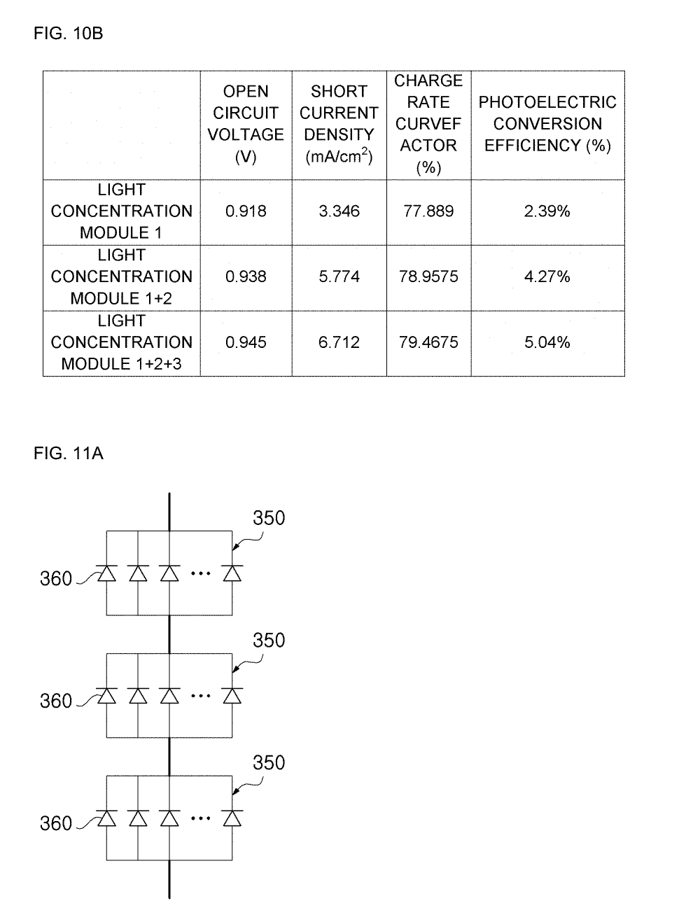

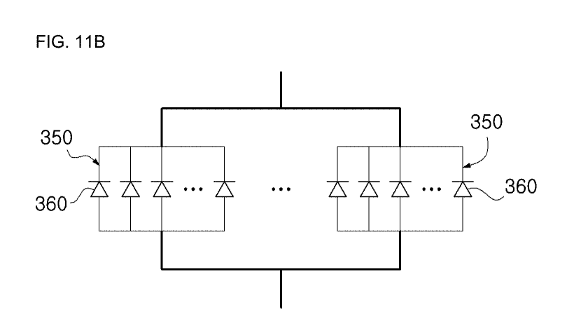

FIG. 9 is a diagram showing a plurality of laminated light concentration modules according to an embodiment of the present disclosure, FIG. 10A is a graph showing the degree of transmittance according to the number of laminated light concentration modules according to an embodiment of the present disclosure, FIG. 10B is a table showing power generation efficiency of the solar cell panel according to an embodiment of the present disclosure, and FIGS. 11a and 11b are diagrams for illustrating a method for connecting plurality of solar cell arrays in series or in parallel according to an embodiment of the present disclosure.

As shown in FIG. 9, if a plurality of light concentration modules 310 is laminated in a height direction (for example, a first light concentration module 310a, a second light concentration module 310b and a third light concentration module 310c are laminated in a height direction), solar cell arrays 350 may be provided according to the number of the light concentration modules 310 at side surfaces of the light concentration modules 310, respectively. At this time, the solar cell arrays 350 provided at the side surfaces of the light concentration modules 310 may be electrically connected to each other in series or in parallel. Here, the pattern 333 may have a width (W) of 100 μm, a height (H) of 100 μm and a cycle (P) of 500 μm.

FIG. 10A exemplarily shows transmittance of light having a visible ray wavelength, when a plurality of light concentration modules 310 (namely, a first light concentration module 310a, a second light concentration module 310b and a third light concentration module 310c are laminated in a height direction) are laminated in FIG. 9. As shown in FIG. 10A, if the number of laminated light concentration modules 310 increases, the light transmittance is lowered, and also, as shown in FIG. 10B, the photoelectric conversion efficiency of the solar cell arrays 350 provided at the side surfaces of the light concentration modules 310 may be enhanced.

Meanwhile, in the case where a plurality of light concentration modules 310 (namely, a first light concentration module 310a, a second light concentration module 310b and a third light concentration module 310c are laminated in a height direction) are laminated and solar cell arrays 350 are respectively provided at the side surfaces of the light concentration modules 310 as in FIG. 9, FIG. 11A shows a case where the plurality of solar cells 360 in each solar cell array 350 are connected in parallel and the plurality of solar cell arrays 350 are connected in series, and FIG. 11B shows a case where the plurality of solar cells 360 in each solar cell array 350 are connected in parallel and the plurality of solar cell arrays 350 are connected in parallel.

FIGS. 11A and 11B just show exemplarity connections of the plurality of solar cell arrays 350, and the plurality of solar cell arrays 350 may be connected in various other ways.

The present disclosure is not limited to the embodiments described above, but it is obvious to those having ordinary skill in the art that the present disclosure may be changed or modified in various ways without departing from the scope thereof. Therefore, such changes or modifications should be regarded as falling into the scope of the appended claims.

### REFERENCE SYMBOLS

| | |
|---|---|
| 100: window | 200: window frame |
| 300: solar cell panel | 310: light concentration module |
| 320: light diffusion layer | 330: light concentration layer |
| 331: pattern | 350: solar cell array |
| 360: solar cell | 370: cell frame |

1. A solar cell panel, comprising:
a light diffusion layer to which light is incident and at which the light is scattered, wherein the light diffusion layer having nano particles disposed at a surface of the light diffusion layer;
a light concentration layer laminated at a lower portion of the light diffusion layer and having a plurality of patterns spaced apart from each other and each one of the plurality of patterns having a cavity shape convex toward the light diffusion layer at a surface thereof opposite to the light diffusion layer so that light passing through the light diffusion layer is reflected and concentrated to a side portion thereof; and
a solar cell array provided at a side surface of the light concentration layer and having a plurality of solar cells arranged along the side surface of the light concentration layer and electrically connected to each other.

2. The solar cell panel according to claim 1,
wherein the plurality of patterns configures a matrix form.

3. The solar cell panel according to claim 2,
wherein the plurality of patterns has a cycle of 1 to 2000 μm.

4. The solar cell panel according to claim 1,
wherein the patterns have a width of 1 to 1000 μm and a height of 1 to 1000 μm.

5. The solar cell panel according to claim 1,
wherein the light concentration layer is formed with a glass substrate, and
wherein the patterns having a cavity shape convex toward the light diffusion layer are formed at a surface thereof opposite to the light diffusion layer by means of etching or laser processing.

6. The solar cell panel according to claim 1,
wherein the light diffusion layer and the light concentration layer configure a single unit light concentration module,
wherein one or more unit light concentration modules are laminated in a height direction, and
wherein the solar cell arrays are provided respectively at sides of the unit light concentration modules according to the number of the unit light concentration modules and electrically connected to each other.

7. A window having a solar cell panel, comprising:
a solar cell panel; and
a window frame coupled along an edge of the solar cell panel,
wherein the solar cell panel includes:
a light concentration module having a light diffusion layer to which light is incident and at which the light is scattered, and a light concentration layer laminated at a lower portion of the light diffusion layer and having a plurality of patterns spaced apart from each other and having a cavity shape convex toward the light diffusion layer at a surface thereof opposite to the light diffusion layer so that light passing through the light diffusion layer is reflected and concentrated to a side portion thereof; and
a solar cell array coupled to a side surface of the light concentration module.

8. The window having a solar cell panel according to claim 7,
wherein the plurality of patterns configures a matrix form.

9. The window having a solar cell panel according to claim 8,
wherein the plurality of patterns has a cycle of 1 to 2000 μm.

10. The window having a solar cell panel according to claim 7,
wherein the patterns have a width of 1 to 1000 μm and a height of 1 to 1000 μm.

11. The window having a solar cell panel according to claim 7,
wherein when a plurality of the light concentration modules is laminated in a height direction, the solar cell arrays are provided respectively at sides of the unit light concentration modules according to the number of the unit light concentration modules and electrically connected to each other.

12. The solar cell panel of claim 1, wherein the solar cell array comprises solar cells and a cell frame supporting a lower surface of the solar cells.

13. The solar cell panel of claim 12, wherein the cell frame comprises an insulation layer closely adhered to a partial region of the lower surface of the solar cell and a conductive layer closely adhered to the lower surface of the solar cell except for the region to which the insulation layer is closely adhered.
